(19) United States
(12) Patent Application Publication
(10) Pub. No.: US 2022/0178228 A1
(43) Pub. Date: Jun. 9, 2022

(54) SYSTEMS AND METHODS FOR DETERMINING GRID CELL COUNT FOR RESERVOIR SIMULATION

(71) Applicant: LANDMARK GRAPHICS CORPORATION, Houston, TX (US)

(72) Inventors: Shivani ARORA, Houston, TX (US); Travis St. George RAMSAY, Hockley, TX (US); Qinghua WANG, Katy, TX (US); Raja Vikram R. PANDYA, Katy, TX (US); Satyam PRIYADARSHY, Katy, TX (US)

(73) Assignee: LANDMARK GRAPHICS CORPORATION, Houston, TX (US)

(21) Appl. No.: 17/438,193

(22) PCT Filed: Apr. 25, 2019
(86) PCT No.: PCT/US2019/029210

§ 371 Date: Sep. 10, 2021

(51) Int. Cl. E21B 43/00; G06F 30/27

(52) U.S. Cl. CPC E21B 43/00; E21B 2200/20; G06F 30/27

(57) ABSTRACT

Systems, methods and computer readable storage media for optimizing a determination of a number of grid cell counts to be used in creating the geocellular grid of an earth, geomechanical or petro-elastic model for reservoir simulation. These may involve determining at least one processing time for a simulation; determining a grid cell count to be used in creating a geocellular grid for the simulation based on the at least one processing time and a number of processors to be used for creating the model; creating the geocellular grid using the grid cell count, and generating a model for the simulation using the geocellular grid.

### TECHNICAL FIELD

The present technology pertains to improvements in generation of computer models. In particular, the present disclosure relates to optimizing number of grid cells to be used in generating computer models based on a given set of computer hardware constraints.

### BACKGROUND

During various phases of natural resource exploration and production, it may be necessary to characterize and model a target reservoir to determine availability and potential of natural resources production in the target reservoir. Petrophysical properties of the target reservoir such as gamma ray, porosity and permeability can be defined for determining a number of grid cells to be used for generating the earth model, which can then be used for reservoir simulation. Reservoir simulation is a computationally intensive process (both in terms of time and cost) and currently there are no methods available to optimize selection of grid cell counts for earth modeling based on simulation time and hardware constraints. Such optimization can improve the reservoir simulation process. With improved modeling, costs can be reduced, potential problems avoided, and improved hydrocarbon production can be achieved.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIGS. 1A-C illustrate example depictions of an oilfield environment for implementation of the disclosure herein, according to one aspect of the present disclosure;

FIG. 2 illustrates a system structure for implementing the present disclosure, according one aspect of the present disclosure;

FIG. 3 illustrates a flow diagram of one implementation of the improvement model disclosed herein;

FIG. 4 illustrates an example neural network, according to one aspect of the present disclosure; and

FIGS. 5A-B illustrate schematic diagram of example computing device and system according to one aspect of the present disclosure.

### DETAILED DESCRIPTION

Various example embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

It will be appreciated that for simplicity and clarity of illustration, where appropriate, reference numerals have been repeated among the different figures to indicate corresponding or analogous elements. In addition, numerous specific details are set forth in order to provide a thorough understanding of the example embodiments described herein. However, it will be understood by those of ordinary skill in the art that the example embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the example embodiments described herein.

Analysis of a target reservoir for production of natural resources such as oil, gas, etc., involves studying various petrophysical properties and a large amount of seismic data. An earth model, a geomechanical model and/or a petro-elastic model is an integral part of such analysis to understand the target reservoir and is used in simulating the reservoir. Such reservoir simulation is performed using high performance cloud based computation resources and/or stationary desktop resources (which can be referred to as cloud and desktop platforms, respectively).

Disclosed herein are systems, methods and computer readable storage media for optimizing a determination of a number of grid cells to be used in creating an earth model (and/or alternatively a geomechanical model and/or a petro-elastic model) for reservoir simulation. This optimization includes using a number of input variables (factors/constraints) to determine a CPU usage time per iteration, which is in turn used in combination with a number of available processors to run the reservoir simulation on, to determine/predict a number of grid cells or grid cell count to create an earth model for reservoir simulation. CPU usage time per iteration and the number of available processors are inputted into a trained neural network model (Artificial Intelligence (AI) based model) to predict a number of grid cells needed to create an earth model using cloud and desktop platforms.

Factors/constraints used in predicting the number of grid cells include, but are not limited to, a time constraint defining a time period needed to run a reservoir simulation and hardware constraint defining hardware configuration of cloud and/or desktop platforms on which the simulation is implemented.

The disclosure herein can be implemented in the context of an oilfield environment having one or more boreholes for the production of hydrocarbons. However, the present disclosure is not limited thereto and can be applied to any type of simulation in which a continuous domain is discretized to study various aspects, behavior thereof.

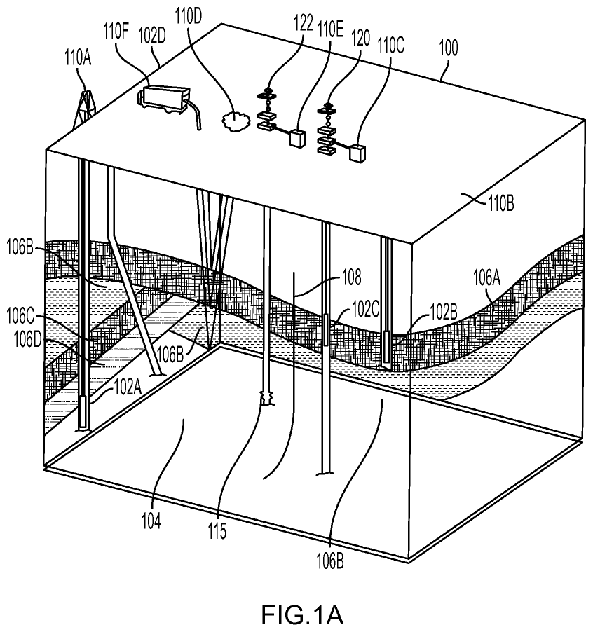

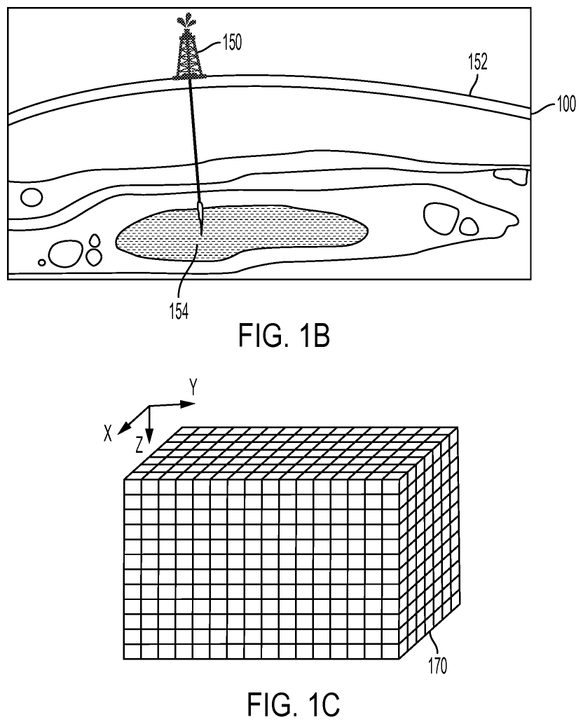

FIGS. 1A-C illustrate example depictions of an oilfield environment for implementation of the disclosure herein, according to one aspect of the present disclosure. FIG. 1A is a schematic of oilfield 100 that can include multiple wells 110A-F which may have tools 102A-D for data acquisition. The multiple wells 110A-F may target one or more natural resource (e.g., hydrocarbon) reservoirs. Moreover, the oilfield 100 has sensors and computing devices positioned at various locations for sensing, collecting, analyzing, and/or reporting data. For instance, well 110A illustrates a drilled well having a wireline data acquisition tool 102A suspended from a rig at the surface for sensing and collecting data, generating well logs, and performing downhole tests which are provided to the surface. Well 110B is currently being drilled with drilling tool 102B which may incorporate additional tools for logging while drilling (LWD) and/or measuring while drilling (MWD). Well 110C is a producing well having a production tool 102C. The tool 102C is deployed from a Christmas tree 120 at the surface (having valves, spools, and fittings). Fluid flows through perforations in the casing (not shown) and into the production tool 102C in the wellbore to the surface. Well 110D illustrates a well having blowout event of fluid from an underground reservoir. The tool 102D may permit data acquisition by a geophysicist to determine characteristics of a subterranean formation and features, including seismic data. Well 110E is undergoing fracturing and having initial fractures 115, with producing equipment 122 at the surface. Well 110F is an abandoned well which had been previously drilled and produced.

The oilfield 100 can include a subterranean formation 104, which can have multiple geological formations 106A-D, such as a shale layer 106A, a carbonate layer 106B, a shale layer 106C, and a sand layer 106D. In some cases, a fault line 108 can extend through one or more of the layers 106A-D.

Sensors and data acquisition tools may be provided around the oilfield 100, multiple wells 110A-E and associated with tools 102A-D. The data may be collected to a central aggregating unit and then provided to a processing unit (a processor). Such processing unit can be communicatively coupled using any known or to be developed wired and/or wireless communication scheme/protocol to sensors and tools 102A-D.

The data collected by such sensors and tools 102A-D can include oilfield parameters, values, graphs, models, predictions, monitor conditions and/or operations, describe properties or characteristics of components and/or conditions below ground or on the surface, manage conditions and/or operations in the oilfield 100, analyze and adapt to changes in the oilfield 100, etc. The data can include, for example, properties of formations or geological features, physical conditions in the oilfield 100, events in the oilfield 100, parameters of devices or components in the oilfield 100, etc.

FIG. 1B is another example depiction of oilfield 100 with oil rig 150 at surface 152 and example reservoir 154 beneath surface 152 accessible via oil rig 150.

Various computer modeling techniques exist by way a reservoir such as reservoir 154 and behavior thereof can be modeled. These modeling techniques can provide a three dimensional array of data values. Such data values may correspond to collected survey data, scaling data, simulation data, and/or other values. Collected survey data, scaling data, and/or simulation data is of little use when maintained in a raw data format. Hence collected data, scaling data, and/or simulation data is sometimes processed to create a data volume, i.e., a three dimensional array of data values such as the data volume 170 of FIG. 1C. Data volume 170 represents a distribution of formation characteristics throughout the survey region. The three-dimensional array comprises uniformly-sized cells, each cell having data values representing one or more formation characteristics for that cell. Examples of suitable formation characteristics include porosity, permeability, and density. Further, stratigraphic features, facies features, and petrophysical features may be applied to the three-dimensional array to represent a static earth model as described herein. The volumetric data format readily lends itself to computational analysis and visual rendering, and for this reason, data volume 170 may be termed a “three-dimensional image” of the survey region (e.g. oilfield 100).

In one example, in order to generate data volume 170, implemented computer reservoir modeling programs require a grid cell count for the geocellular reservoir model to be generated or for a gridless reservoir model to be rendered onto a grid with the requisite purpose of numerical flow simulation. With higher cell counts, generated data volume 170 can model greater detail of the assumed behavior of reservoir 154 more accurately at a cost of significant computational resource consumption and time. On the other hand, the lower the cell count, with lower cell counts, generated data volume 170 can model the assumed behavior of reservoir 154 less accurately at a lower cost of computational resource consumption and time. Accordingly, optimization of the number of grid cells to be used for generating data volume 170 can be of significant value to end users and relevant businesses.

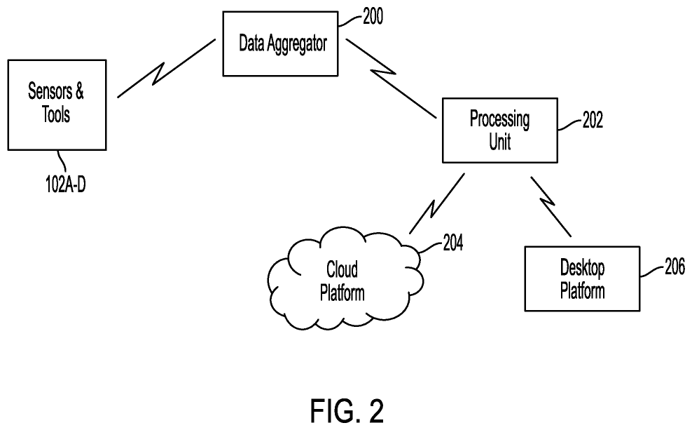

FIG. 2 illustrates a system structure for implementing the present disclosure, according one aspect of the present disclosure. As shown in FIG. 2, sensors and tools 102A-D are communicatively coupled to data aggregator 200. Data aggregator 200 can be a computer/processing component that is physically located close to sensors and tools 102A-D or remotely connected thereto using known or to be developed wired/wireless communication schemes. Data aggregator 200 can continuously receive and collect/aggregator various types of data collected by sensors and tools 102-A-D.

Data aggregator 200 can in turn be communicatively coupled for processing unit 202, which can be any type of known or to be developed terminal used by an operator for analyzing a potential reservoir such as oilfield 100. An example of processing unit 202 can be a desktop work station, a tablet, a laptop, etc.

Processing unit 202 can be communicatively coupled to a cloud platform 204 for reservoir simulation and/or can alternatively use on-site desktop platform 206 for reservoir simulation.

Cloud platform 204 can be a single or a collection of remote computational resources such as processors that are offered for use by a cloud service provider. Cloud platform 204 can be a public, private and/or a hybrid platform accessible by operator at processing unit 202. Cloud platform 204 can execute a simulator (which is a computer program) to simulate a reservoir, for example.

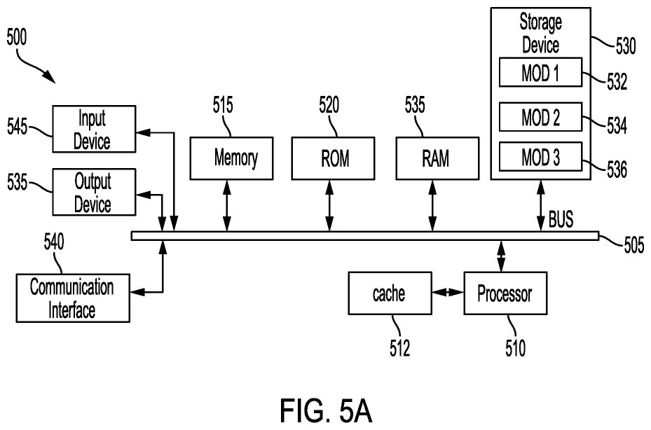

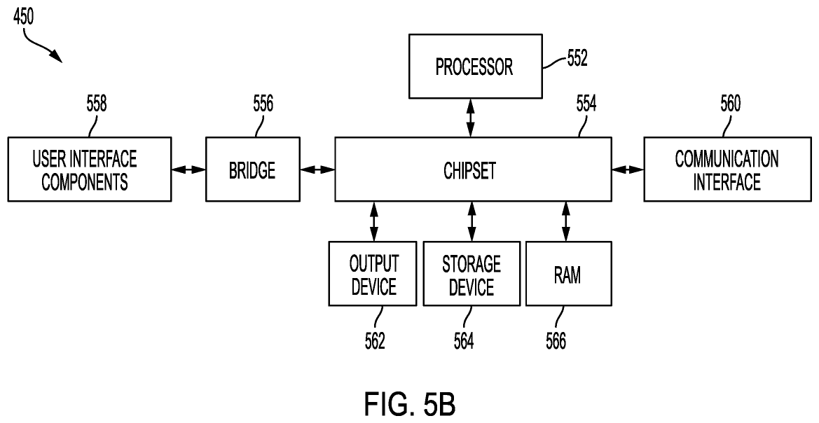

Desktop platform 206 can be a single or a collection of on-site computation resources such as processors that are connected to processing unit 202 for use in reservoir simulation. Desktop platform 204 can execute a simulator (which is a computer program) to simulate a reservoir, for example. Example structure and components of will be further described with reference to FIG. 5A-B.

As noted above, current modeling methods used for reservoir simulation depend on the development of an earth model based on defined stratigraphy and petrophysical properties of a potential reservoir (e.g., based on data collected by sensors and tools 102A-D). These stratigraphic and petrophysical properties can influence a number of grid cells to be used in generating the earth model (e.g., data volume 170). This method of determining a number of grid cells can result in creating either an earth model that is too fine (greater amount of grid cells) for a reservoir simulator to use efficiently given computational resource limitations of workstations or cost constraints in elastic cloud platforms on which the simulator is being executed or too coarse (fewer grid cells) of an earth model that fails to preserve significant geological features of the potential reservoir. Hereinafter, example embodiments will be described according to which determination of a number of grid cells is partially based on time and resource constraints of platforms being used to execute the reservoir simulation on. This provides a faster and more reliable quantitative method for determining the number of grid cells to be used for creating the earth model that is reservoir simulation ready. This would also provide an improved user experience in creating reservoir simulation ready earth models.

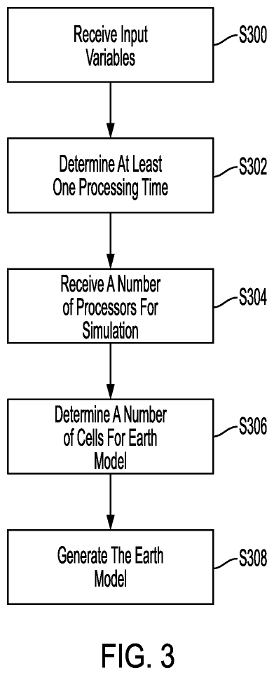

FIG. 3 illustrates a flow diagram of one implementation of the improvement model disclosed herein. FIG. 3 will be described from the perspective of processing unit 202 of FIG. 2. However, it will be understood that processing unit 202 can have one or more memories having computer-readable instructions stored thereon, which when executed by one or more associated processors (as will be further described with reference to FIG. 5A-B), cause the one or more associated processors to implemented the functionalities described with reference to FIG. 3.

At S300, processing unit 202 receives input variables. Such input variables may be received via a user terminal (input device) corresponding to (coupled to) processing unit 202 and operated by an operator. Such input variables include, but are not limited to, a desired CPU execution time (first input), a simulated production time (second input) and minimum and maximum time steps for simulation (third inputs). CPU time defines a given instance of running a reservoir simulation program (e.g., 30 minutes, an hour, 2 hours, etc.), which may be specified by as a desired simulation run time, a range of run times or a maximum run time. For example, a desired simulation run time could be ‘3 days’, a range of simulation run times could be 2 days to 10 days and a cutoff simulation run time could be 10 days. Simulated production time can indicate a period of time over which behavior of a potential/target reservoir (e.g., oilfield 100) is to be observed (e.g., 7000 days). Third inputs indicate a minimum and maximum time steps to be undertaken by the simulator during the execution of the program (e.g., 1 day time steps (minimum time step) and 100 day steps (maximum time step)). In one example, example input variables such as first, second and third inputs described above, can define a time constraint on determining a number of grid cells to be used for creating an earth model.

In one example, input variables can further include type of platform being used for the simulation—workstation, laptop, or cloud including (processor speed, RAM, number of cores, implemented hyper-threading), stratigraphy and fault/horizon framework, definition of net reservoir according to petrophysical and/or elastic properties, Euler characteristic of flow unit in petrophysical property model, flow unit thickness, etc.

At S302, processing unit 202 determines at least one processing time for simulating a reservoir, based on the input variables received at S300. Processing unit 202 can determine a processing time for each time step received as an input. Therefore, when both minimum and maximum time steps are provided as input, processing unit 202 can generate a processing time for the minimum time step and a processing time for a maximum time step. Such processing time can also be referred to as a CPU time per iteration, which can be determined as follows.

Processing unit 202 determines a number of iterations for simulation. Processing unit 202 can determine a minimum number of iterations for a maximum time step received at S300 and a maximum number of iterations for a minimum time step received at S300. In one example, a minimum number of iterations is given by a ratio of the production time received at S300 and the maximum time step per:

minimum number of iterations=production time/maximum time step (1)

Furthermore, a maximum number of iterations is given by a ration of the production time to the minimum time step per:

maximum number of iterations=production time/minimum time step (2)

Based on equations (1) and (2), processing unit 202 can determine a minimum and maximum processing time (CPU time) per iteration. For example, a minimum CPU time per iteration can be determined as a ratio of simulation time received at S300 and the maximum number of iterations of equation (2) per:

maximum CPU time per iteration=simulation time/minimum number of iterations (3)

Furthermore, a maximum CPU time per iteration can be determined as a ratio of simulation time received at S300 and the minim number of iterations of equation (1) per:

minimum CPU time per iteration=simulation time/maximum number of iterations (3)

Having determined a CPU time per iteration for each input time step, at S304, processing unit 202 receives a number of processors of cloud platform and/or desktop platform to be used for running the reservoir simulation. In one example, the number of processors may be a fourth input received simultaneously with other input variables at S300.

At S306, processing unit 202 determines/predicts a number of grid cells for generating an earth model based on the number of processors and the maximum or minimum CPU time per iteration (processing time) determined at S302.

In one example, processing unit 202 inputs the number of processors and maximum and/or minimum processing time into a neural network model (which may also be referred to as a neural architecture) and receives as output of the neural network model a number of cells (grid cell counts) for creating the reservoir simulation ready earth model. Processing unit 202 may input the number of processors and maximum and/or minimum processing time into a different neural network model depending on whether a reservoir simulation is implemented on a cloud platform or a desktop platform.

Each neural network model (cloud neural network or desktop neural network) may be trained using data collected from simulations running on corresponding cloud or desktop platforms. As more and more simulations are executed and data therefrom are collected, such neural networks are better trained and accuracy of their predictions improves. The data collected from simulations, with which neural networks can be trained, include but are not limited to, cell grid counts (number of cells) used initially and adjustments made thereto (e.g., upscaling or downscaling the grid count) during the simulation process, whether created earth models (based on such grid counts) resulted in acceptable simulations or not, etc.

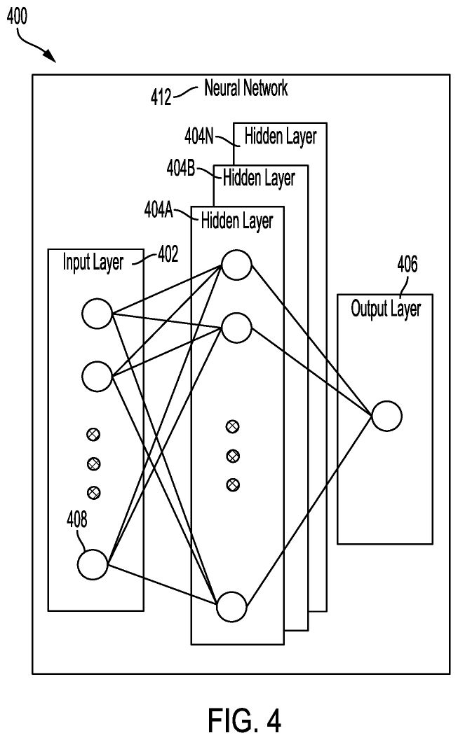

FIG. 4 illustrates an example neural network, according to one aspect of the present disclosure. Example neural network 400 can be used as the cloud neural network and/or the desktop neural network. In one example, different neural network models can be used for cloud neural network or desktop neural network.

In FIG. 4, neural network 412 includes an input layer 402 which includes input data including, but not limited to, the number of processors, the number of cores of each processor or processing unit and maximum and/or minimum processing time at S306, data received from sensors and tools 102A-D, etc.

Neural network 412 can include hidden layers 404A through 404N (collectively “404” hereinafter). Hidden layers 404 can include n number of hidden layers, where n is an integer greater than or equal to one. The number of hidden layers can be made to include as many layers as needed for the given application. Neural network 412 further includes an output layer 406 that provides an output resulting from the processing performed by hidden layers 304. In one illustrative example, output layer 406 can provide the predicted number of cells at S306.

Neural network 412 can be a multi-layer deep learning network of interconnected nodes. Each node can represent a piece of information. Information associated with the nodes is shared among the different layers and each layer retains information as information is processed. In some cases, neural network 412 can include a feed-forward network, in which case there are no feedback connections where outputs of the network are fed back into itself. In some cases, the neural network 412 can include a recurrent neural network, which can have loops that allow information to be carried across nodes while reading in input.

Information can be exchanged between nodes through node-to-node interconnections between the various layers. Nodes of input layer 402 can activate a set of nodes in first hidden layer 404A. For example, as shown, each of input nodes of input layer 402 is connected to each of the nodes of the first hidden layer 404A. Nodes of hidden layer 404A can transform the information of each input node by applying activation functions to the information. The information derived from the transformation can then be passed to and can activate nodes of next hidden layer (e.g., 404B), which can perform their own designated functions. Example functions include convolutional, up-sampling, data transformation, pooling, and/or any other suitable functions. Output of the hidden layer (e.g., 404B) can then activate nodes of next hidden layer (e.g., 404/V), and so on. Output of the last hidden layer can activate one or more nodes of output layer 406, at which point an output is provided. In some cases, while nodes (e.g., node 408) in neural network 412 are shown as having multiple output lines, a node has a single output and all lines shown as being output from a node represent the same output value.

In some cases, each node or interconnection between nodes can have a weight that is a set of parameters derived from the training of neural network 412. For example, an interconnection between nodes can represent a piece of information learned about the interconnected nodes. The interconnection can have a numeric weight that can be tuned (e.g., based on a training dataset), allowing neural network 412 to be adaptive to inputs and able to learn as more data is processed.

Neural network 412 can be pre-trained to process the features from the data in input layer 402 using different hidden layers 404 in order to provide the output through output layer 406. In an example in which neural network 412 is used to identify objects in images, neural network 412 can be trained using training data of past instances of execution of reservoir simulation models using various collected data, number of processors used, CPU processing times, etc.

In some cases, neural network 412 can adjust the weights of the nodes using a training process called backpropagation. Backpropagation can include a forward pass, a loss function, a backward pass, and a weight update. The forward pass, loss function, backward pass, and parameter update is performed for one training iteration. The process can be repeated for a certain number of iterations for each set of training images until neural network 412 is trained enough so that the weights of the layers are accurately tuned.

For a first training iteration for neural network 412, the output can include values that do not give preference to any particular class due to the weights being randomly selected at initialization. For example, if the output is a vector with probabilities that the object includes different classes, the probability value for each of the different classes may be equal or at least very similar (e.g., for ten possible classes, each class may have a probability value of 0.1). With the initial weights, neural network 412 is unable to determine low level features and thus cannot make an accurate determination of what the classification of the object might be. A loss function can be used to analyze errors in the output. Any suitable loss function definition can be used.

The loss (or error) can be high for the first training images since the actual values will be different than the predicted output. The goal of training is to minimize the amount of loss so that the predicted output is the same as the training label. Neural network 412 can perform a backward pass by determining which inputs (weights) most contributed to the loss of the network, and can adjust the weights so that the loss decreases and is eventually minimized.

A derivative of the loss with respect to the weights can be computed to determine the weights that contributed most to the loss of the network. After the derivative is computed, a weight update can be performed by updating the weights of the filters. For example, weights can be updated so that they change in the opposite direction of the gradient. A learning rate can be set to any suitable value, with a high learning rate including larger weight updates and a lower value indicating smaller weight updates.

Neural network 412 can include any suitable deep network. One example includes a convolutional neural network (CNN), which includes an input layer and an output layer, with multiple hidden layers between the input and out layers. The hidden layers of a CNN include a series of convolutional, nonlinear, pooling (for downsampling), and fully connected layers. In other examples, the neural network 112 can represent any other deep network other than a CNN, such as an autoencoder, a deep belief nets (DBNs), a Recurrent Neural Networks (RNNs), etc.

Referring back to FIG. 3, at S308 and with a predicted number of cell counts, processing unit 202 can generate (create) a geocellular grid for the earth model (e.g., data volume 170) by running the simulation on either cloud platform 204 and/or desktop platform 206. The predicted/determined number of grid cells can be used by any known or to be developed geological modeling software to create the geocellular component of an earth model that ultimately leads to the simulation of production from the target reservoir such as reservoir 154.

While a target reservoir with potential for production of natural resources such as oil and field has been used above to describe the concepts of the present disclosure, the simulation process and the examples of determining a grid cell count are not limited to reservoir simulation but can be applied to any type of simulation, in which a domain or a real world object is to be discretized for analysis purposes. Other applications of the grid cell count methods of the present disclosure include solid mechanics applications, fluid mechanics applications, etc.

The disclosure now turns to various components and system architectures that can be utilized as processing unit 202 to implement the functionalities described above.

FIGS. 5A-B illustrates schematic diagram of example computing device and system according to one aspect of the present disclosure. FIG. 5A illustrates a computing device which can be employed to perform various steps, methods, and techniques disclosed above. The more appropriate embodiment will be apparent to those of ordinary skill in the art when practicing the present technology. Persons of ordinary skill in the art will also readily appreciate that other system embodiments are possible.

Example system and/or computing device 500 includes a processing unit (CPU or processor) 510 and a system bus 505 that couples various system components including the system memory 515 such as read only memory (ROM) 520 and random access memory (RAM) 535 to the processor 510. The processors disclosed herein can all be forms of this processor 510. The system 500 can include a cache 512 of high-speed memory connected directly with, in close proximity to, or integrated as part of the processor 510. The system 500 copies data from the memory 515 and/or the storage device 530 to the cache 512 for quick access by the processor 510. In this way, the cache provides a performance boost that avoids processor 510 delays while waiting for data. These and other modules can control or be configured to control the processor 510 to perform various operations or actions. Other system memory 515 may be available for use as well. The memory 515 can include multiple different types of memory with different performance characteristics. It can be appreciated that the disclosure may operate on a computing device 500 with more than one processor 510 or on a group or cluster of computing devices networked together to provide greater processing capability. The processor 510 can include any general purpose processor and a hardware module or software module, such as module 1 532, module 2 534, and module 3 536 stored in storage device 530, configured to control the processor 510 as well as a special-purpose processor where software instructions are incorporated into the processor. The processor 510 may be a self-contained computing system, containing multiple cores or processors, a bus, memory controller, cache, etc. A multi-core processor may be symmetric or asymmetric. The processor 510 can include multiple processors, such as a system having multiple, physically separate processors in different sockets, or a system having multiple processor cores on a single physical chip. Similarly, the processor 510 can include multiple distributed processors located in multiple separate computing devices, but working together such as via a communications network. Multiple processors or processor cores can share resources such as memory 515 or the cache 512, or can operate using independent resources. The processor 510 can include one or more of a state machine, an application specific integrated circuit (ASIC), or a programmable gate array (PGA) including a field PGA (FPGA).

The system bus 505 may be any of several types of bus structures including a memory bus or memory controller, a peripheral bus, and a local bus using any of a variety of bus architectures. A basic input/output (BIOS) stored in ROM 520 or the like, may provide the basic routine that helps to transfer information between elements within the computing device 500, such as during start-up. The computing device 500 further includes storage devices 530 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. The storage device 530 can include software modules 532, 534, 536 for controlling the processor 510. The system 500 can include other hardware or software modules. The storage device 530 is connected to the system bus 505 by a drive interface. The drives and the associated computer-readable storage devices provide nonvolatile storage of computer-readable instructions, data structures, program modules and other data for the computing device 500. In one aspect, a hardware module that performs a particular function includes the software component stored in a tangible computer-readable storage device in connection with the necessary hardware components, such as the processor 510, bus 505, and so forth, to carry out a particular function. In another aspect, the system can use a processor and computer-readable storage device to store instructions which, when executed by the processor, cause the processor to perform operations, a method or other specific actions. The basic components and appropriate variations can be modified depending on the type of device, such as whether the device 500 is a small, handheld computing device, a desktop computer, or a computer server. When the processor 510 executes instructions to perform “operations”, the processor 510 can perform the operations directly and/or facilitate, direct, or cooperate with another device or component to perform the operations.

Although the exemplary embodiment(s) described herein employs the hard disk 530, other types of computer-readable storage devices which can store data that are accessible by a computer, such as magnetic cassettes, flash memory cards, digital versatile disks (DVDs), cartridges, random access memories (RAMs) 535, read only memory (ROM) 520, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with the computing device 500, an input device 545 represents any number of input mechanisms, such as a microphone for speech, a touch-sensitive screen for gesture or graphical input, keyboard, mouse, motion input, speech and so forth. An output device 535 can also be one or more of a number of output mechanisms known to those of skill in the art. In some instances, multimodal systems enable a user to provide multiple types of input to communicate with the computing device 500. The communications interface 540 generally governs and manages the user input and system output. There is no restriction on operating on any particular hardware arrangement and therefore the basic hardware depicted may easily be substituted for improved hardware or firmware arrangements as they are developed.

For clarity of explanation, the illustrative system embodiment is presented as including individual functional blocks including functional blocks labeled as a “processor” or processor 510. The functions these blocks represent may be provided through the use of either shared or dedicated hardware, including, but not limited to, hardware capable of executing software and hardware, such as a processor 510, that is purpose-built to operate as an equivalent to software executing on a general purpose processor. For example the functions of one or more processors presented in FIG. 6A may be provided by a single shared processor or multiple processors. (Use of the term “processor” should not be construed to refer exclusively to hardware capable of executing software.) Illustrative embodiments may include microprocessor and/or digital signal processor (DSP) hardware, read-only memory (ROM) 520 for storing software performing the operations described below, and random access memory (RAM) 535 for storing results. Very large scale integration (VLSI) hardware embodiments, as well as custom VLSI circuitry in combination with a general purpose DSP circuit, may also be provided.

The logical operations of the various embodiments are implemented as: (1) a sequence of computer implemented steps, operations, or procedures running on a programmable circuit within a general use computer, (2) a sequence of computer implemented steps, operations, or procedures running on a specific-use programmable circuit; and/or (3) interconnected machine modules or program engines within the programmable circuits. The system 500 shown in FIG. 6A can practice all or part of the recited methods, can be a part of the recited systems, and/or can operate according to instructions in the recited tangible computer-readable storage devices. Such logical operations can be implemented as modules configured to control the processor 510 to perform particular functions according to the programming of the module. For example, FIG. 6A illustrates three modules Mod1 532, Mod2 534 and Mod3 536 which are modules configured to control the processor 510. These modules may be stored on the storage device 530 and loaded into RAM 535 or memory 515 at runtime or may be stored in other computer-readable memory locations.

One or more parts of the example computing device 500, up to and including the entire computing device 500, can be virtualized. For example, a virtual processor can be a software object that executes according to a particular instruction set, even when a physical processor of the same type as the virtual processor is unavailable. A virtualization layer or a virtual “host” can enable virtualized components of one or more different computing devices or device types by translating virtualized operations to actual operations. Ultimately however, virtualized hardware of every type is implemented or executed by some underlying physical hardware. Thus, a virtualization compute layer can operate on top of a physical compute layer. The virtualization compute layer can include one or more of a virtual machine, an overlay network, a hypervisor, virtual switching, and any other virtualization application.

The processor 510 can include all types of processors disclosed herein, including a virtual processor. However, when referring to a virtual processor, the processor 510 includes the software components associated with executing the virtual processor in a virtualization layer and underlying hardware necessary to execute the virtualization layer. The system 500 can include a physical or virtual processor 510 that receive instructions stored in a computer-readable storage device, which cause the processor 510 to perform certain operations. When referring to a virtual processor 510, the system also includes the underlying physical hardware executing the virtual processor 510.

FIG. 5B illustrates an example computer system 550 having a chipset architecture that can be used in executing the described method and generating and displaying a graphical user interface (GUI). Computer system 550 is an example of computer hardware, software, and firmware that can be used to implement the disclosed technology. System 550 can include a processor 552, representative of any number of physically and/or logically distinct resources capable of executing software, firmware, and hardware configured to perform identified computations. Processor 552 can communicate with a chipset 554 that can control input to and output from processor 552. In this example, chipset 554 outputs information to output 562, such as a display, and can read and write information to storage device 564, which can include magnetic media, and solid state media, for example. Chipset 554 can also read data from and write data to RAM 566. A bridge 556 for interfacing with a variety of user interface components 585 can be provided for interfacing with chipset 554. Such user interface components 585 can include a keyboard, a microphone, touch detection and processing circuitry, a pointing device, such as a mouse, and so on. In general, inputs to system 550 can come from any of a variety of sources, machine generated and/or human generated.

Chipset 554 can also interface with one or more communication interfaces 560 that can have different physical interfaces. Such communication interfaces can include interfaces for wired and wireless local area networks, for broadband wireless networks, as well as personal area networks. Some applications of the methods for generating, displaying, and using the GUI disclosed herein can include receiving ordered datasets over the physical interface or be generated by the machine itself by processor 552 analyzing data stored in storage 564 or 566. Further, the machine can receive inputs from a user via user interface components 585 and execute appropriate functions, such as browsing functions by interpreting these inputs using processor 552.

It can be appreciated that example systems 500 and 550 can have more than one processor 510/552 or be part of a group or cluster of computing devices networked together to provide greater processing capability.

Embodiments within the scope of the present disclosure may also include tangible and/or non-transitory computer-readable storage devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### STATEMENTS OF THE DISCLOSURE INCLUDE:

Statement 1: A predictive modeling method including determining at least one processor for a simulation; determining a grid cell count to be used in creating a geocellular grid for the simulation based on the at least one processing time and a number of processors to be used for creating the model; creating the geocellular grid using the grid cell count; and generating a model for the simulation using the geocellular grid.

Statement 2: The predictive modeling method of statement 1, further including receiving a first input, a second input and at least one third input, the first input specifying a simulation time for using a simulation platform to create the model, the second input specifying a duration of time over which an underlying object is to be simulated, the at least one third input identifying a time step for the simulation; and determining the at least one processing time based on the first input, the second input and the at least one third input.

Statement 3: The predictive modeling method of statement 1, wherein the at least one third input includes a minimum time step and a maximum time step.

Statement 4: The predictive modeling method of statement 3, wherein the at least one processing time includes a minimum processing time corresponding to the minimum time step and a maximum processing time corresponding to the maximum time step.

Statement 5: The predictive modeling method of statement 1, wherein determining the grid cell count includes inputting the at least one processing time and the number of processors into a neural network model; and receiving an output of the neural network model as the grid cell count.

Statement 6: The predictive modeling method of statement 5, wherein the neural network model is one of a first model for cloud based simulation or a second model for desktop machine based simulation.

Statement 7: The predictive modeling method of statement 1, wherein the model is an earth, geomechanical or petro-elastic model for examining natural resource availability within a target reservoir and the model is used to generate a reservoir simulation model for the target reservoir.

Statement 8: A device includes one or more memories having computer-readable instructions stored therein; and one or more processors configured to execute the computer-readable instructions to determine at least one processing time for a simulation; determine a grid cell count to be used in creating a geocellular grid for the simulation based on the at least one processing time and a number of processors to be used for creating the model; create the geocellular grid using the grid cell count; and generate a model for the simulation using the geocellular grid.

Statement 9: The device of statement 8, wherein the one or more processors are further configured to execute the computer-readable instructions to receive a first input, a second input and at least one third input, the first input specifying a simulation time for using a simulation platform to create the model, the second input specifying a duration of time over which an underlying object is to be simulated, the at least one third input identifying a time step for the simulation, and determine the at least one processing time for based on the first input, the second input and the at least one third input.

Statement 10: The device of statement 8, wherein the at least one third input includes a minimum time step and a maximum time step.

Statement 11: The device of statement 10, wherein the at least one processing time includes a minimum processing time corresponding to the minimum time step and a maximum processing time corresponding to the maximum time step.

Statement 12: The device of statement 8, wherein the one or more processors are configured to execute the computer-readable instructions to input the at least one processing time and the number of processors into a neural network model; and determine the grid cell count as an output of the neural network model.

Statement 13: The device of statement 12, wherein the neural network model is one of a first model for cloud based simulation or a second model for desktop, workstation or laptop machine based simulation.

Statement 14: The device of statement 8, wherein the model is an earth, geomechanical, petro-elastic model for examining natural resource availability within a target reservoir; and the model is used to generate a reservoir simulation model for the target reservoir.

Statement 15: one or more non-transitory computer-readable media include computer-readable instructions, which when executed by one or more processors, cause the one or more processors to determine at least one processing time for a simulation; determine a grid cell count to be used in creating a geocellular grid for the simulation based on the at least one processing time and a number of processors to be used for creating the model; create the geocellular grid using the grid cell count and generate a model for the simulation using the geocellular grid.

Statement 16: The one or more non-transitory computer-readable media of statement 15, wherein execution of the computer-readable instructions by the one or more processors, further cause the one or more processors to receive a first input, a second input and at least one third input, the first input specifying a simulation time for using a simulation platform to create the model, the second input specifying a duration of time over which an underlying object is to be simulated, the at least one third input identifying a time step for the simulation, and determine the at least one processing time based on the first input, the second input and the at least one third input.

Statement 17: The one or more non-transitory computer-readable media of statement 15, wherein the at least one third input includes a minimum time step and a maximum time step.

Statement 18: The one or more non-transitory computer-readable media of statement 17, wherein the at least one processing time includes a minimum processing time corresponding to the minimum time step and a maximum processing time corresponding to the maximum time step.

Statement 19: The one or more non-transitory computer-readable media of statement 15, wherein execution of the computer-readable instructions by the one or more processors, further cause the one or more processors to input the at least one processing time and the number of processors into a neural network model; and determine the grid cell count as an output of the neural network model.

Statement 20: The one or more non-transitory computer-readable media of statement 19, wherein the neural network model is one of a first model for cloud based simulation or a second model for desktop, workstation, or laptop machine based simulation.

Although a variety of information was used to explain aspects within the scope of the appended claims, no limitation of the claims should be implied based on particular features or arrangements, as one of ordinary skill would be able to derive a wide variety of implementations. Further and although some subject matter may have been described in language specific to structural features and/or method steps, it is to be understood that the subject matter defined in the appended claims is not necessarily limited to these described features or acts. Such functionality can be distributed differently or performed in components other than those identified herein. Rather, the described features and steps are disclosed as possible components of systems and methods within the scope of the appended claims.

1. A predictive modeling method comprising:
determining at least one processing time for a simulation;
determining a grid cell count to be used in creating a geocellular grid for the simulation based on the at least one processing time and a number of processors to be used for creating the model;
creating the geocellular grid using the grid cell count; and
generating a model for the simulation using the geocellular grid.

2. The predictive modeling method of claim 1, further comprising:
receiving a first input, a second input and at least one third input, the first input specifying a simulation time for using a simulation platform to create the model, the second input specifying a duration of time over which an underlying object is to be simulated, the at least one third input identifying a time step for the simulation; and
determining the at least one processing time based on the first input, the second input and the at least one third input

3. The predictive modeling method of claim 1, wherein the at least one third input includes a minimum time step and a maximum time step.

4. The predictive modeling method of claim 3, wherein the at least one processing time includes a minimum processing time corresponding to the minimum time step and a maximum processing time corresponding to the maximum time step.

5. The predictive modeling method of claim 1, wherein determining the grid cell count comprises:
inputting the at least one processing time and the number of processors into a neural network model; and
receiving an output of the neural network model as the grid cell count.

6. The predictive modeling method of claim 5, wherein the neural network model is one of a first model for cloud based simulation or a second model for desktop, workstation or laptop machine based simulation.

7. The predictive modeling method of claim 1, wherein
the model is an earth, geomechanical or petro-elastic model for examining natural resource availability within a target reservoir; and
the model is used to generate a reservoir simulation model for the target reservoir.

8. A device comprising:
one or more memories having computer-readable instructions stored therein; and
one or more processors configured to execute the computer-readable instructions to:
determine at least one processing time for a simulation;
determine a grid cell count to be used in creating a geocellular grid for the simulation based on the at least one processing time and a number of processors to be used for creating the model;
create the geocellular grid using the grid cell count; and
generate a model for the simulation using the geocellular grid.

9. The device of claim 8, wherein the one or more processors are further configured to execute the computer-readable instructions to:
receive a first input, a second input and at least one third input, the first input specifying a simulation time for using a simulation platform to create the model, the second input specifying a duration of time over which an underlying object is to be simulated, the at least one third input identifying a time step for the simulation; and
determine the at least one processing time for based on the first input, the second input and the at least one third input.

10. The device of claim 8, wherein the at least one third input includes a minimum time step and a maximum time step.

11. The device of claim 10, wherein the at least one processing time includes a minimum processing time corresponding to the minimum time step and a maximum processing time corresponding to the maximum time step.

12. The device of claim 8, wherein the one or more processors are configured to execute the computer-readable instructions to:
input the at least one processing time and the number of processors into a neural network model; and
determine the grid cell count as an output of the neural network model.

13. The device of claim 12, wherein the neural network model is one of a first model for cloud based simulation or a second model for desktop, workstation or laptop machine based simulation.

14. The device of claim 8, wherein
the model is an earth, geomechanical, petro-elastic model for examining natural resource availability within a target reservoir; and
the model is used to generate a reservoir simulation model for the target reservoir.

15. One or more non-transitory computer-readable media comprising computer-readable instructions, which when executed by one or more processors, cause the one or more processors to:
determine at least one processing time for a simulation;
determine a grid cell count to be used in creating a geocellular grid for the simulation based on the at least one processing time and a number of processors to be used for creating the model;
create the geocellular grid using the grid cell count; and
generate a model for the simulation using the geocellular grid.

16. The one or more non-transitory computer-readable media of claim 15, wherein execution of the computer-readable instructions by the one or more processors, further cause the one or more processors to:
receive a first input, a second input and at least one third input, the first input specifying a simulation time for using a simulation platform to create the model, the second input specifying a duration of time over which an underlying object is to be simulated, the at least one third input identifying a time step for the simulation; and
determine the at least one processing time based on the first input, the second input and the at least one third input.

17. The one or more non-transitory computer-readable media of claim 15, wherein the at least one third input includes a minimum time step and a maximum time step.

18. The one or more non-transitory computer-readable media of claim 17, wherein the at least one processing time includes a minimum processing time corresponding to the minimum time step and a maximum processing time corresponding to the maximum time step.

19. The one or more non-transitory computer-readable media of claim 15, wherein execution of the computer-readable instructions by the one or more processors, further cause the one or more processors to:
input the at least one processing time and the number of processors into a neural network model; and
determine the grid cell count as an output of the neural network model.

20. The one or more non-transitory computer-readable media of claim 19, wherein the neural network model is one of a first model for cloud based simulation or a second model for desktop, workstation or laptop machine based simulation.
